(19) United States
(12) Patent Application Publication
(10) Pub. No.: US 2007/0215324 A1
(43) Pub. Date: Sep. 20, 2007

(54) Liquid-cooled heat dissipater

(76) Inventor: Wen-Han Chen, Sanchong City (TW)

Correspondence Address: TROXELL LAW OFFICE PLLC, SUITE 1404, 5205 LEESBURG PIKE, FALLS CHURCH, VA, 22041, US

(21) Appl. No.: 11/373,967

(22) Filed: Mar. 14, 2006

(51) Int. Cl. H05K 7/20

(52) U.S. Cl. 165/80.4; 165/170; 361/699; 257/714

(57) ABSTRACT

A liquid-cooled heat dissipater is composed of a fin, a substrate, and a plurality of screwing members. One or more than one interconnected grooves are concaved on a surface at one side of the fin, and are connected to a liquid inlet junction and a liquid outlet junction on the substrate, respectively. Accordingly, a heat exchange of the liquid between the liquid inlet junction and the liquid outlet junction can be performed through the grooves of fin, so as form a narrow and thin shape of entire heat dissipater, thereby achieving a function of space saving.

### BACKGROUND OF THE INVENTION

(a) Field of the Invention

The present invention relates to a liquid-cooled heat dissipater, and more particularly to a liquid-cooled heat dissipater which is used for cooling down a heating element, with a narrow and thin shape to save a space to be occupied, and with a function of effectively reducing a squeezing problem which occurs in installation.

(b) Description of the Prior Art

As the advancement of modern technology, an integrated circuit or CPU (Central Processing Unit) is designed mainly toward high-speed computation and processing, which will definitely generate larger heat under this condition of high-speed computation and processing. However, a temperature rise caused by the heat is proportional to the computation speed of CPU. Therefore, a heat dissipation effect of an ordinary conventional fan-type heat dissipating device has already been unable to keep up with a rate of temperature rise under the condition of high-speed computation.

Furthermore, in an ordinary liquid-cooled heat dissipating device, a heat dissipater, an interior of which is provided with a space for containing liquid, is usually used. The shape of heat dissipater is wide and thick due to the installation of liquid-containing space; therefore, when a water pipe is connected for use, the water pipe is easy to squeeze at peripheral equipment to cause an ill contact, or even to cause a water-leakage problem at a connector of water pipe.

Accordingly, how to remove the aforementioned problems is a technical issue to be solved by the present inventor.

### SUMMARY OF THE INVENTION

The primary object of the present invention is to provide a liquid-cooled heat dissipater for cool downing a heating element, which is provided with a narrow and thin shape to save a space to be occupied, and is able to effectively reduce a problem of squeezing in installation.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view of the present invention.

FIG. 2 shows an exploded view of the present invention.

FIG. 3 shows a schematic view of an embodiment of the present invention.

FIG. 4 shows a second schematic view of an embodiment of the present invention.

FIG. 5 shows a third schematic view of an embodiment of the present invention.

### DETAILED DESCRIPTION OF THE PREFERRED EMBODIMENTS

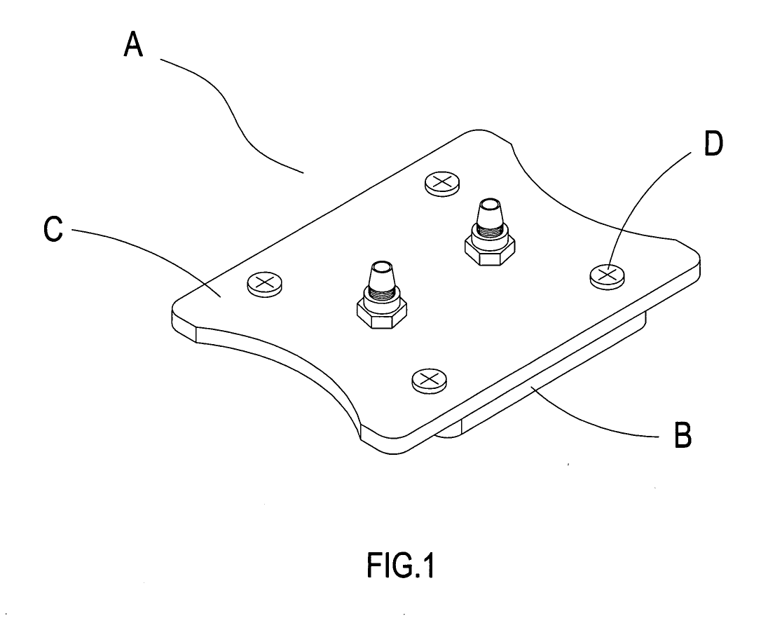

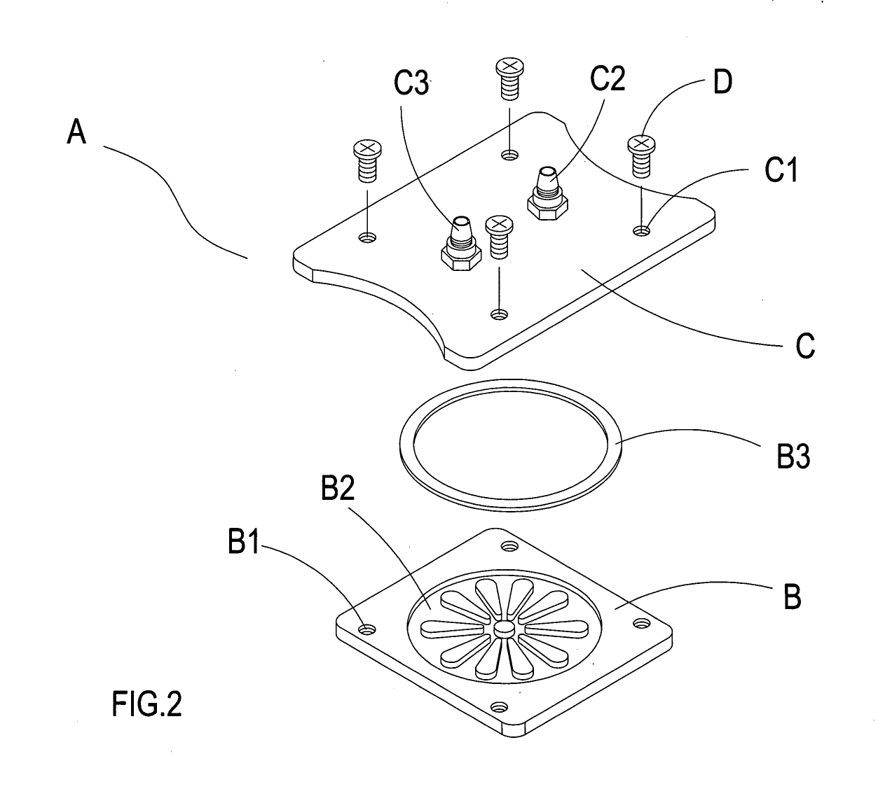

Referring to FIG. 1 and FIG. 2, a heat dissipater A is primarily composed of a fin B, a substrate C, and a plurality of screwing members D, wherein the fin B is provided with a plurality of screw holes B1, and is provided with one or more than one interconnected grooves B2 concaved on a surface at one side of the fin B. The substrate C is installed on the fin B, and is provided with a plurality of through-holes C1 which are corresponding to positions of the screw holes B1. The screwing members D are transfixed into the through-holes C1 separately, and are locked to the screw holes B1 for tightly fixing. In addition, a liquid inlet junction C2 and a liquid outlet junction C3 are configured on the substrate C, and are connected to the grooves B2 of fin B, respectively.

A gasket ring B3 is installed between the fin B and the substrate C to increase coherence between the fin B and the substrate C. The fin B is used to absorb heat from a heating element, and the grooves B which are concaved on the surface of fin B are used to provide for a space of heat exchange of the liquid between the liquid inlet junction C2 and the liquid outlet junction C3, so as to form a narrower and thinner shape to the heat dissipater A, thereby saving space utilization.

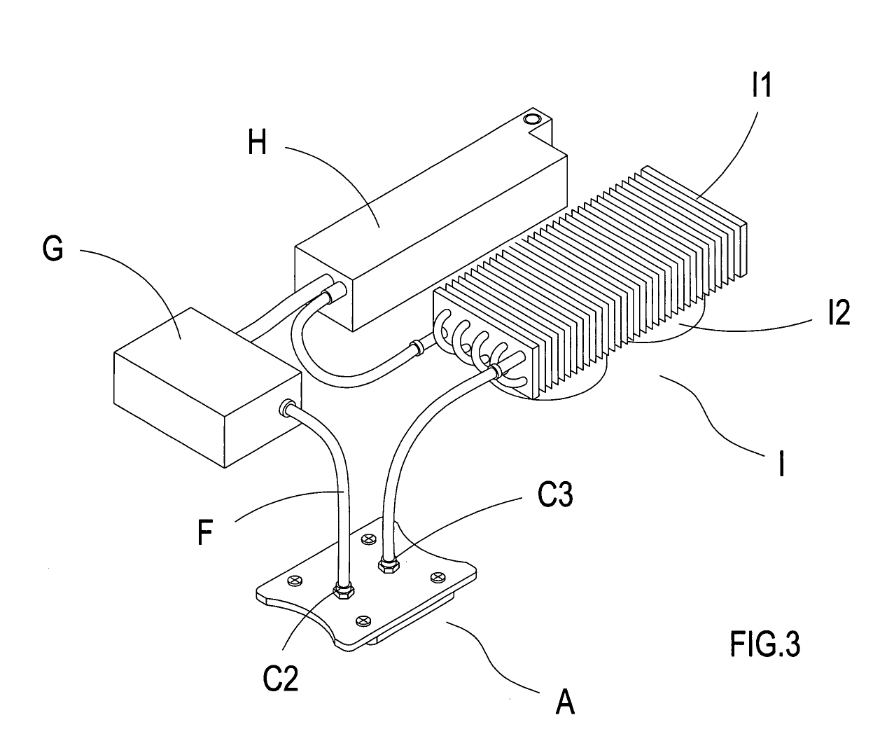

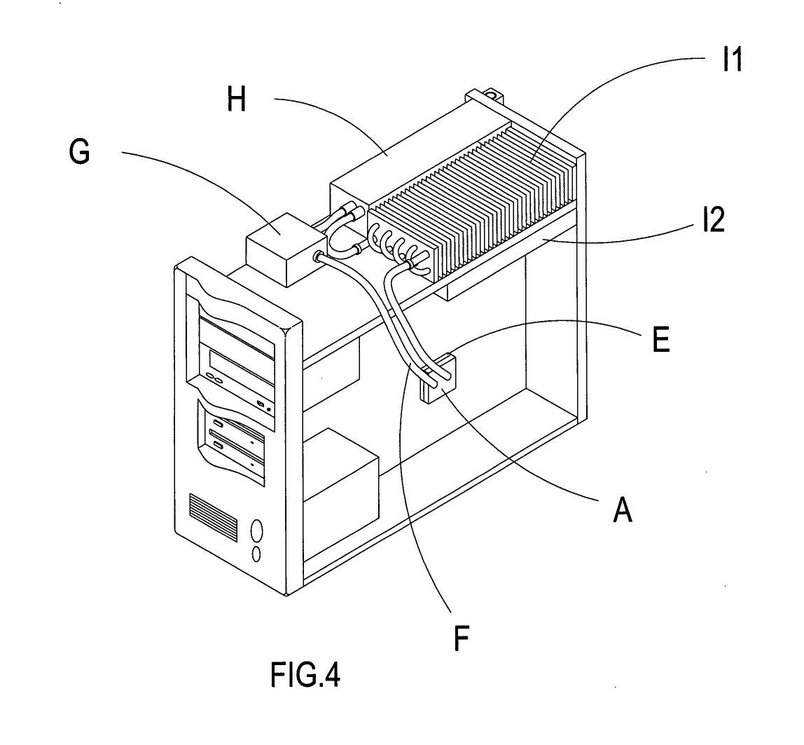

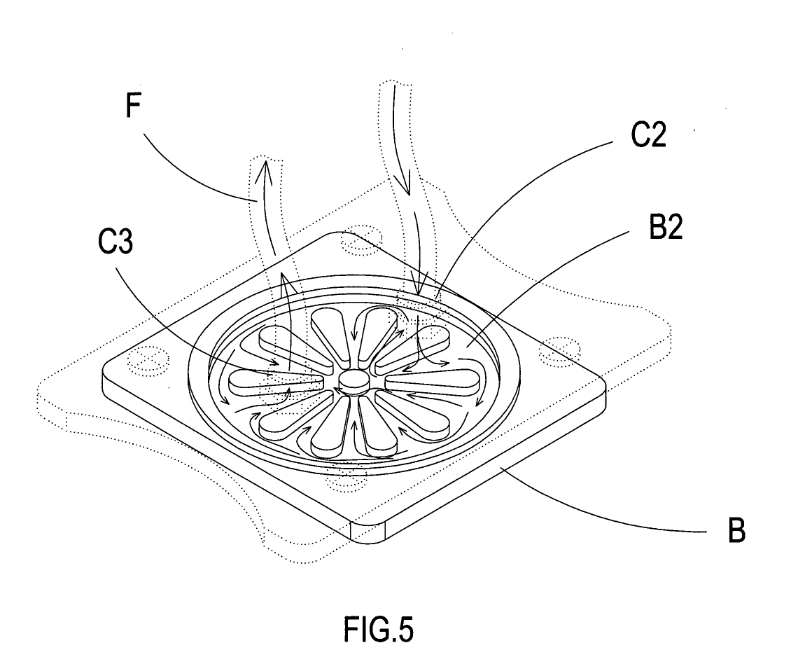

Referring to FIGS. 3 to 5, the heat dissipater A is affixed on a heating element E which can be further an integrated circuit, a CPU, a storage device, a light emitting device, a transformer, and other related device which will generate heat. Water pipes F are connected to the liquid inlet junction C2 and the liquid outlet junction C3 of heat dissipater A respectively, and are also connected with a motor G, a water tank H, and heat dissipating equipment 1, thereby forming a path of serial connection. Accordingly, when the motor G is activated to operate, liquid in the water tank H can flow cyclically through the path of serial connection.

The heat generated from the heating element E is absorbed by the heat dissipater A, and is then cooled down in the grooves B2 of fin B through the liquid flowing in from the liquid inlet junction C2. Next, the liquid with temperature is expelled out from the liquid outlet junction C3 to the heat dissipating equipment I for cooling. Accordingly, the heat absorbed by the fin B will be cyclically taken away, so as to quickly reduce the temperature of heating element E, wherein the heat dissipating equipment I is performing the heat dissipation through a matching with fins I1 and a cooling fan I2.

In addition, the fin B can be further made by a Copper material, an Aluminum material, an alloy material, a ceramic material, and other related material having an effect of high heat conduction and high heat dissipation.

To further manifest the advancement and practicability of the present invention, the present invention is compared with a conventional application as below:

Shortcomings of a conventional application
1. The heat dissipater of liquid-cooled heat dissipating device is easy to occupy the space.
2. According to item 1, the connected water pipe is easy to squeeze at the peripheral equipment to cause the ill contact.
3. According to item 2, it is easy to cause the problem of water-leakage at the junction of water pipe.

Advantages of the present invention
1. The grooves of fin are used to provide a space for heat exchange with liquid, so as to form a smaller shape of the heat dissipater, thereby effectively saving space utilization.
2. According to item 1, it can reduce the problem that the connected water pipe will squeeze at the peripheral equipment.
3. According to item 2, it can effective avoid the problem of water-leakage to the water pipe.
4. It is provided with advancement and practicability.
5. It is provided with an industrial competitiveness.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A liquid-cooled heat dissipater comprising a fin which is used to absorb heat generated from a heating element, is provided with one or more than one interconnected grooves concaved on a surface at one side of the fin, and is provided with a plurality of screw holes on the surface thereof; a substrate which is installed on the fin, is provided with a plurality of through-holes corresponding to positions of the screw holes, and is configured with a liquid inlet junction and a liquid outlet junction connected to the grooves of fin, respectively; and a plurality of screwing members which are transfixed into the through-holes of substrate and are locked into the screw holes on the fin for tightly fixing.

2. The liquid-cooled heat dissipater according to claim 1, wherein the heat dissipater further includes a gasket ring which is configured between the fin and the substrate, to increase coherence between the fin and the substrate.

3. The liquid-cooled heat dissipater according to claim 1, wherein the liquid inlet junction of substrate is connected to the liquid outlet junction through the grooves of fin.

4. The liquid-cooled heat dissipater according to claim 1, wherein the fin is further made by a copper material, an aluminum material, an alloy material, a ceramic material, and other related material having an effect of high heat conduction and high heat dissipation.

5. The liquid-cooled heat dissipater according to claim 1, wherein the heating element can be further an integrated circuit, a CPU, a storage device, a light emitting device, a transformer, and other related device which can generate heat.
